(19) United States
(12) Patent Application Publication
(10) Pub. No.: US 2004/0175937 A1
(43) Pub. Date: Sep. 9, 2004

(54) Metallic coating for electrical connectors

(76) Inventor: Erik Orwoll, Phoenix, AZ (US)

Correspondence Address: WEISS & MOY PC, 4204 NORTH BROWN AVENUE, SCOTTSDALE, AZ, 85251, US

(21) Appl. No.: 10/435,889

(22) Filed: May 12, 2003

Related U.S. Application Data
(63) Continuation-in-part of application No. 10/382,751, filed on Mar. 5, 2003.

(51) Int. Cl. H01L 21/44

(52) U.S. Cl. 438/674

(57) ABSTRACT

A method for a metallic conversion process on a contact comprising: providing a metallic contact; forming intermetallic compounds on the metallic contact; and removing a portion of the intermetallic compounds formed on the metallic contact.

### RELATED APPLICATIONS

This patent application is a continuation in part of Ser. No. 10/382,751; filed Mar. 5, 2003, in the name of Erik Orwoll, and entitled “ELECTRO-CHEMICAL CLEANING PROCESS FOR ELECTRICAL CONNECTORS”.

### BACKGROUND OF THE INVENTION

1. Field of the Invention

This invention relates to electrical connectors, and more specifically, to a metallic coating applied to electrical contacts which increases the life of electrical connectors.

2. Description of the Prior Art

In semiconductor manufacturing, integrated circuits (IC's) are packaged in several different formats which allow them to be soldered to a circuit board. These packaging types include: BGA, QFP, QFN, CSP, and many other styles.

The testing of the IC's is a very important step in the production of quality semiconductor devices. A number of different tests may be performed on the integrated circuit to identify whether the circuit is operating correctly and whether or not the circuit is likely to malfunction in the future. The packages (chips) are tested both during and after the manufacturing process to verify functionality. The testing occurs by contacting the leads (IO's) of the device with electrical contacts where test signals can be passed through the device. This process typically utilizes wafer probes to contact the bare die, and utilizes test connectors to test die that is in its final packaged form. Burn-In and HAST testing often occurs in conjunction with the other tests to determine infant mortality rates and endurance levels. Programmable devices are subjected to additional interface with electrical connectors during the final “programming” production phase. These programming connectors are subject to the same solder contamination and failure issues.

Each time a test occurs, the leads of the device are mechanically contacted with an electrical test device to establish an electrical path. As this mechanical contact is made, small amounts of solder are transferred to the contact point of the electrical tester. As this process is repeated, solder continues to be transferred to the contact point. Each layer of transferred solder will oxidize, which increases the electrical resistance of the connection. Eventually, the resistance becomes so high that the degraded electrical signal prevents the device from being tested properly.

When this failure occurs, the tester must be taken out of service. The tester is then repaired, replaced, or cleaned. Repair and replacement is costly, and the current cleaning methods can be costly, ineffective, and unreliable. Connectors which are soldered to the circuit board often cannot be replaced without damaging the circuit board.

It should also be noted that the transfer of solder to the mechanical point of contact can be accelerated at high temperatures. Solder oxidation also occurs at a higher rate. Therefore, connectors used at high temperature (such as Burn-In) may fail sooner than those used at ambient temperature.

The majority of connectors are a copper based conductor that has been plated with Nickel and hard Gold. Other plating materials have been developed for electrical connectors over the years to address the issue of solder contamination (i.e. Palladium Nickel, Palladium Cobalt, etc.), but none of these materials have significantly increased the life of the connectors. Each year, over 500 million dollars worth of connectors are disposed of during the manufacture of semiconductor devices, and the majority of these connectors fail due to solder contamination. Cleaning methods have been developed to restore failed connectors to functional condition, but they do not extend the initial life of the connector.

Hard Gold plating is the most common surface plating used in electrical connectors because it is conductive, corrosion resistant, and relatively hard. However, because solder tends to adhere to Gold, solder transfers to the connectors as they are used. This transferred solder oxidizes, which, in turn, increases resistance of the connector. Solder transfer will continue to occur until a point is reached where electrical failure occurs.

Therefore, a need existed to provide an improved electrical contact. The improved electrical contact must be reliable and cost effective. The improved electrical contact must be able to resist solder adhesion, provide high electrical conductivity, resist mechanical wear, and maintain low contact resistance while mated with solder interfaces.

### SUMMARY OF THE INVENTION

In accordance with one embodiment of the present invention, it is an object of the present invention to provide an improved electrical contact.

It is another object of the present invention to provide an improved electrical contact that is reliable and cost effective.

It is another object of the present invention to provide an improved electrical contact that resists solder adhesion, provides high electrical conductivity, resists mechanical wear, and maintains low contact resistance while mated with solder interfaces.

### BRIEF DESCRIPTION OF THE EMBODIMENTS

In accordance with one embodiment of the present invention, a method for a metallic conversion process on a contact comprising: providing a metallic contact; forming intermetallic compounds on the metallic contact; and removing a portion of the intermetallic compounds formed on the metallic contact.

In accordance with another embodiment of the present invention, a method for a metallic conversion process on a contact comprising: providing a metallic contact; plating the metallic contact with Nickel, Gold and Tin; heating the metallic contact to form intermetallic compounds on the metallic contact; and removing a portion of the intermetallic compounds formed on the metallic contact by stripping the Tin from the metallic contact.

The foregoing and other objects, features, and advantages of the invention will be apparent from the following, more particular, description of the preferred embodiments of the invention, as illustrated in the accompanying drawing.

### BRIEF DESCRIPTION OF THE DRAWINGS

The invention itself, as well as a preferred mode of use, and advantages thereof, will best be understood by reference to the following detailed description of illustrated embodiment when read in conjunction with the accompanying drawings, wherein like reference numerals and symbols represent like elements.

FIG. 1 is a simplified sketch of the intermetallic compounds formed on the metallic contact.

FIG. 2 is a cross-section view of the intermetallic compounds formed on the metallic contact.

FIG. 3 depicted the Gold surface on the metallic contact.

FIG. 4 is a data table showing resistance data.

### DETAILED DESCRIPTION OF THE PREFERRED EMBODIMENT

The invention consists of a metallic conversion process which produces a Gold metallic material that is infused with intermetallic Au—Sn compounds. The process also applies to other common plating combinations such as Palladium Cobalt, where the resultant is a Palladium metallic material infused with Pd—Sn compounds.

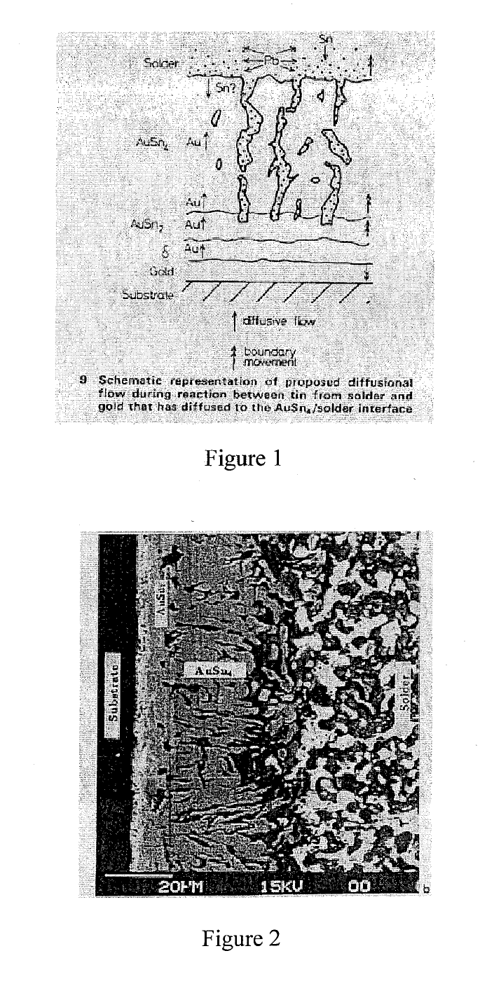

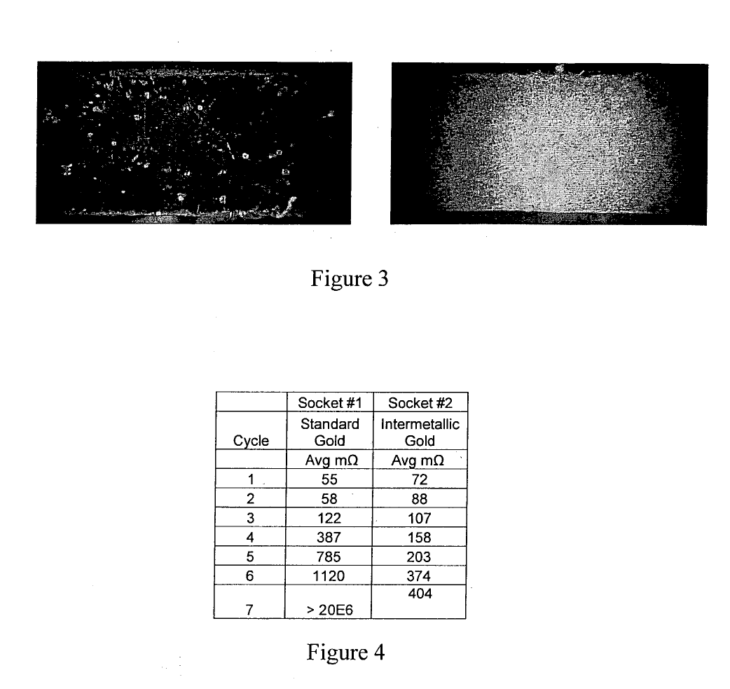

Referring to FIGS. 1-4 the present invention will be described. A Copper or Beryllium Copper contact is plated with Nickel (50-200 micro-inch), Gold (30 minimum micro-inch), and Tin (10-100 micro-inch). The contact is then heated to a temperature of approximately 150-190 Celsius for a period of approximately 2-6 hours. During this period, the Tin and Gold interact through a process called solid state diffusion. The Gold and Tin metals combine to form a variety of precipitates of Au—Sn, known as intermetallic compounds (also commonly referred to as polyatomic). These compounds grow as columnar grains throughout the Gold/Tin layers. FIG. 1 is a sketch by Hannech and Hall.

FIG. 2 is a SEM cross-section photograph showing intermetallic growth in a typical solder/Gold interface. The Tin is then stripped from the connector (Chemically or Electro-Chemically). The remaining material surface is similar to standard hard Gold, but there are notable differences: The surface has a slightly textured, 3-Dimensional profile, and the surface has columnar intermetallic formations which occupy a percentage of the gold surface area. These intermetallic regions exhibit reduced adhesion with solder, and also act as micro-penetrators, which pierce the oxide layer of the mating electrical component (such as an IC package).

The thickness of the Tin layer determines the wear and electrical properties of the coating. A thicker Tin coating provides more wear resistance, but it also increases electrical contact resistance. A thicker Tin coating also requires longer time for the diffusion process to occur.

Au—Sn compounds are harder than Gold or Tin, and they are as resistant to corrosion as Gold. Electrical conductivity of the Au—Sn compounds is only slightly less than Gold, but it exceeds the Gold-Tin alloys.

Intermetallic compounds have been studied for years because of their importance in the Electronics Industry. Intermetallic compounds form whenever Tin is in contact with Gold or a similar material such as Palladium. Solder joint failures are a common problem in the electronics industry, and the failures are caused by intermetallic compounds which cause solder to become brittle. Intermetallic compounds continue to form as long as the solder remains in contact with the Gold plating.

### EXAMPLE 1

Type of Connector: 1.27 mm Pitch BGA Burn-In Socket

Two connectors were tested. Socket #1 was populated with standard Gold plated contacts. Socket #2 was populated with the intermetallic Gold contacts.

Socket #1:

The contacts in the socket consisted of the following construction: Beryllium Copper base material, plated with Nickel (50-200 micro-inch), and Gold (30 micro-inch).

Socket #2:

The contacts in the socket consisted of the following construction: Beryllium Copper base material, plated with Nickel (50-200 micro-inch), Gold (30 micro-inch), and Tin (50-100 micro-inch). The contacts were heated to 190 degrees Celsius for a period of 4.5 hours. Nu Signal's Electro-Chemical Cleaning Process was applied to the contacts to remove the Tin. The Tin removal process was applied to the connector for a period of 44 minutes.

Each connector was tested with a 4 wire (LLCR) meter to determine the resistance of the contacts with a mated BGA test device. The resistance was measured using two pins at a time. Five sets of pairs were identified, and the same set of pins was measured after each test cycle.

A package was inserted into the socket, and the socket was actuated. Each test cycle consisted of 1000 actuations with the package in place, followed by a 1 hour bake at 125 degrees Celsius (with the package removed). A new production package was used for each test cycle. Resistance measurements were taken after each test cycle using the test package.

Failure was identified as any reading that exceeded 1000 milliohms. Although the Intermetallic Gold connector had a higher initial resistance, the resistance remained lower over time, and did not increase at nearly the rate of the Standard Gold connector.

While the invention has been particularly shown and described with reference to preferred embodiments thereof, it will be understood by those skilled in the art that the foregoing and other changes in form and details may be made therein without departing from the spirit and scope of the invention.

What is claimed is:

1. A method for a metallic conversion process on a contact comprising:
providing a metallic contact;
forming intermetallic compounds on the metallic contact; and
removing a portion of the intermetallic compounds formed on the metallic contact.

2. The method of claim 1 wherein forming intermetallic compounds on the metallic contact comprises:
plating the metallic contact with Nickel, Gold and Tin; and
heating the metallic contact.

3. The method of claim 2 wherein removing a portion of the intermetallic compounds formed on the metallic contact comprises stripping the Tin from the metallic contact.

4. The method of claim 2 wherein removing a portion of the intermetallic compounds formed on the metallic contact further comprises chemically stripping the Tin from the metallic contact.

5. The method of claim 2 wherein removing a portion of the intermetallic compounds formed on the metallic contact further comprises electro-chemically stripping the Tin from the metallic contact.

6. The method of claim 2 wherein platting the metallic contact with Nickel, Gold and Tin further comprises:
plating the metallic contact with approximately 50-200 micro-inches of Nickel;
plating the metallic contact with a minimum of 30 micro-inches of Gold; and
plating the metallic contact with approximately 10-100 micro-inches of Tin.

7. The method of claim 2 wherein heating the metallic contact further comprises heating the contact to a temperature of approximately 150-190° C.

8. The method of claim 7 wherein heating the metallic contact to a temperature of approximately 150-190° C. further comprises heating the metallic contact to a temperature of approximately 150-190° C. for approximately 2-6 hours.

9. A method for a metallic conversion process on a contact comprising:
providing a metallic contact;
plating the metallic contact with Nickel, Gold and Tin;
heating the metallic contact to form intermetallic compounds on the metallic contact; and
removing a portion of the intermetallic compounds formed on the metallic contact by stripping the Tin from the metallic contact.

10. The method of claim 9 wherein removing a portion of the intermetallic compounds formed on the metallic contact further comprises chemically stripping the Tin from the metallic contact.

11. The method of claim 9 wherein removing a portion of the intermetallic compounds formed on the metallic contact further comprises electro-chemically stripping the Tin from the metallic contact.

12. The method of claim 9 wherein platting the metallic contact with Nickel, Gold and Tin further comprises:
plating the metallic contact with approximately 50-200 micro-inches of Nickel;
plating the metallic contact with a minimum of 30 micro-inches of Gold; and
plating the metallic contact with approximately 10-100 micro-inches of Tin.

13. The method of claim 9 wherein heating the metallic contact further comprises heating the contact to a temperature of approximately 150-190° C.

14. The method of claim 9 wherein heating the metallic contact to a temperature of approximately 150-190° C. further comprises heating the metallic contact to a temperature of approximately 150-190° C. for approximately 2-6 hours.
